(19) United States
(12) Patent Application Publication
(10) Pub. No.: US 2025/0063779 A1
(43) Pub. Date: Feb. 20, 2025

(54) DEVICES AND METHODS FOR FORMING DEVICES WITH INNER SPACERS

(71) Applicant: Taiwan Semiconductor Manufacturing Company, Ltd., Hsinchu (TW)

(72) Inventors: Che-Lun Chang, Hsinchu (TW); Kuan-Ting Pan, Taipei (TW)

(73) Assignee: Taiwan Semiconductor Manufacturing Company, Ltd., Hsinchu (TW)

(21) Appl. No.: 18/449,348

(22) Filed: Aug. 14, 2023

(51) Int. Cl. H01L 29/06; H01L 21/8238; H01L 27/092; H01L 29/08; H01L 29/423; H01L 29/66; H01L 29/775; H01L 29/786

(52) U.S. Cl. CPC H01L 29/0673; H01L 21/823807; H01L 21/823814; H01L 27/092; H01L 29/0847; H01L 29/42392; H01L 29/66439; H01L 29/66545; H01L 29/775; H01L 29/78696

(57) ABSTRACT

Provided are devices and methods for forming devices. An exemplary method includes etching a cavity in a vertical direction into a fin structure including at least one semiconductor nanosheet overlying a sacrificial layer, wherein the cavity is formed with a sidewall; recessing the sacrificial layer by a lateral distance to a recessed surface; forming an inner spacer laterally adjacent to the recessed surface of the sacrificial layer, wherein the inner spacer has a lateral width greater than the lateral distance; and growing epitaxial material in the cavity to form a source/drain region laterally adjacent to the inner spacer.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device during a stage of fabrication, in accordance with some embodiments.

FIG. 2 is a cross-sectional view of a semiconductor device during the stage of fabrication shown in FIG. 1, in accordance with some embodiments.

FIG. 3 is a focused cross-section view of the semiconductor device of FIG. 2, illustrating an inner spacer, in accordance with some embodiments.

FIG. 4 is a cross-sectional view of a semiconductor device during the stage of fabrication shown in FIG. 1, in accordance with some embodiments.

FIG. 5 is a focused cross-section view of the semiconductor device of FIG. 4, illustrating an inner spacer, in accordance with some embodiments.

FIG. 6 is a flow chart illustrating a method, in accordance with some embodiments.

FIGS. 7-11 are perspective views of a structure of the semiconductor device during successive stages of fabrication, in accordance with some embodiments.

FIG. 12 is a cross-sectional view of the structure of the semiconductor device in FIG. 11, in accordance with some embodiments.

FIG. 13 is a perspective view of a structure of the semiconductor device during a successive stage of fabrication, in accordance with some embodiments.

FIG. 14 is a cross-sectional view of the structure of the semiconductor device in FIG. 13, in accordance with some embodiments.

FIGS. 15-23 are cross-sectional views of a portion of structure of the semiconductor device during successive stages of fabrication, in accordance with some embodiments.

FIG. 24 is a cross-sectional view of a structure of the semiconductor device during a further stage of fabrication, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is ±ten percent. Thus, “about ten” means nine to eleven.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Certain embodiments herein are generally related to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as a gate-all-around (GAA) device. A GAA device includes any device that has its gate structure, or portion thereof, formed on 4-sides of a channel region (e.g., surrounding a portion of a channel region).

Structures presented herein also include embodiments that have channel regions in the form of nanosheets. The term “nanosheet” designates any material portion with nanoscale, or even microscale dimensions, and having an elongated shape, regardless of the cross-sectional shape of this portion. Thus, this term designates both circular and substantially circular cross-section elongated material portions, e.g., nanowires, and beam or bar-shaped material portions including for example a cylindrical or substantially rectangular cross-section.

Presented herein are embodiments that may have one or more channel regions associated with a single, contiguous gate structure. However, one of ordinary skill would recognize that the teaching can apply to a single channel region or any number of channel regions. One of ordinary skill may recognize other examples of semiconductor devices that may benefit from aspects of the present disclosure.

As described herein, a method is performed to increase the lateral thickness of inner spacers. Further, a method is performed to form inner spacers that extend past the end of channel regions, e.g., past the end of semiconductor nanosheets, and into the source/drain regions. In some embodiments, the inner spacers may be provided to increase AC gain in a device. For example, the inner spacers may be used in a gate-all-around (GAA) device to increase AC gain. In some embodiments, the inner spacers may be provided to reduce the effective capacitance (C_{eff}) of a device.

Further, certain embodiments herein provide for the formation of low-K dielectric cores or air gaps within inner spacers. The presence of low-K dielectric cores or air gaps within inner spacers may reduce effective capacitance.

It is noted that while the Figures and description recite the structure of a gate-all-around (GAA) device, it is contemplated that the methods described herein may be used to fabricate other types of devices, and that the devices described herein may be other types of devices.

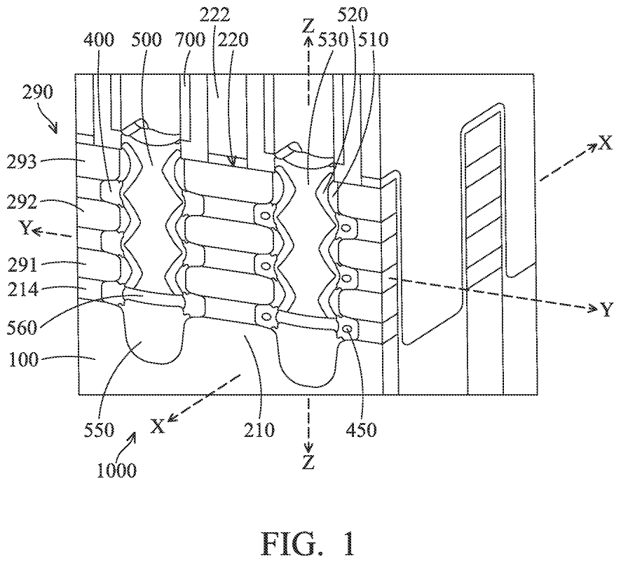

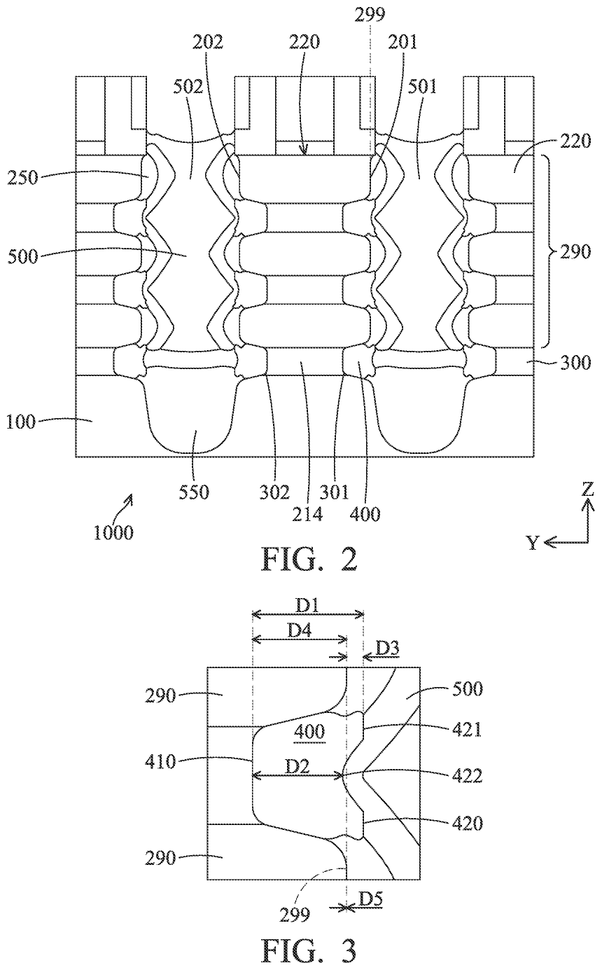

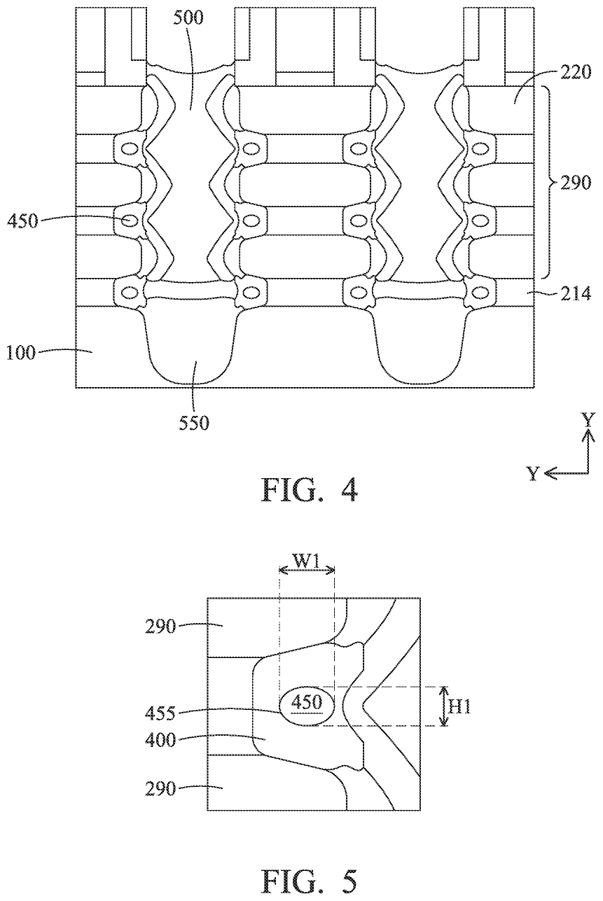

For purposes of the discussion that follows, FIGS. 1-5 illustrates a portion of a semiconductor device 1000 fabricated according to methods described herein. FIG. 1 is a perspective view illustrating two embodiments of inner spacers, i.e., inner spacers without internal cores or air gaps and inner spacers with internal cores or air gaps. FIG. 2 is a cross-sectional view of the device of FIG. 1, having inner spacers without cores or air gaps. FIG. 3 is a focused view of an inner spacer of FIG. 2. FIG. 4 is a cross-sectional view of the device of FIG. 1, having inner spacers with cores or air gaps. FIG. 5 is a focused view of an inner spacer of FIG. 4.

As shown in FIGS. 1, 2 and 4, device 1000 includes a substrate 100, such as a semiconductor substrate.

In some embodiments, the substrate 100 may be formed from and include silicon. Alternatively or additionally, the substrate 100 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP. In yet another alternative, the substrate 100 is a semiconductor on insulator (SOI). The plurality of conductive and non-conductive thin films may comprise an insulator or a conductive material. For example, the conductive material comprises a metal such as aluminum (Al), copper (Cu), tungsten (W), nickel (Ni), titanium (Ti), and platinum (Pt) and, thereof an alloy of the metals and other conductive substances such as nitrides (e.g., titanium nitride (TiN), tantalum nitride (TaN) and carbides (e.g., titanium carbide (TiC), tantalum carbide (TaC). The insulator material may include silicon oxide and silicon nitride.

As shown in FIGS. 1, 2 and 4, the device 1000 further includes fin structures 220. Fin structures 220 extend in the Y-direction and are spaced from one another in the X-direction. The fin structures 220 may be formed from the substrate 100. For example, the fin structures 220 may include a mesa portion 210 that is formed from the substrate 200. Further, the fin structures 220 may include semiconductor nanosheets 290, including nanosheets 291, 292, and 293. While FIG. 1 illustrates three nanosheets 290, the fin structures 220 of device 1000 may include any suitable number of nanosheets 290. Each fin structure 220 may include a lowest semiconductor nanosheet 291 distanced from a mesa portion 210 in the vertical Z-direction, and nanosheets 292 and 293 distanced from the lowest semiconductor nanosheet 291 in the vertical Z-direction.

At the stage of fabrication of FIG. 1, sacrificial layers 214 are located above and below the semiconductor nanosheets 290. An exemplary sacrificial layer 214 is a semiconductor that may be selectively etched. For example, the semiconductor nanosheets 290 may be silicon and the sacrificial layers 214 may be silicon germanium (SiGe).

As shown in FIGS. 1-5, the device 1000 also includes inner spacers 400. At the stage of fabrication of FIGS. 1-5, the inner spacers 400 are located at each end of each sacrificial layer 214. Inner spacers 400 may be formed with or without cores or air gaps 450. As used herein, an “air gap” is a volume that includes no solid feature, but may include a gas, such as the ambient gas during formation. In some embodiments, the ambient gas is air.

The device 1000 further includes source/drain regions 500. As used herein, “source/drain region(s)” may refer to a source region or a drain region, individually or collectively depending on the context. The source/drain regions 500 may include multiple layers, such as multiple epitaxial layers 510, 520, and 530, and may be formed with desire materials for an NFET or a PFET.

As further shown in FIG. 2, a bottom epitaxial region 550 may be located under the source/drain regions 500. Further, a bottom dielectric layer 560 may be located between the bottom isolation region 550 and the source/drain region 500 and extend between opposite inner spacers 400.

At the stage of fabrication of FIGS. 1-5, a sacrificial gate structure 222 is located over each stack of semiconductor nanosheets 290 and sacrificial layers 214.

Further, a spacer structure 700 is located adjacent to the sacrificial gate structure 222.

Referring to FIGS. 2-5, device 1000 includes a first source/drain region 501 distanced from a second source/drain region 502 in the lateral Y-direction. Further, the device 1000 includes a fin structure 220 including semiconductor nanosheets 290. Each semiconductor nanosheet 290 extends in the lateral Y-direction from a first end 201, adjacent the first source/drain region 501, to a second end 202, adjacent the second source/drain region 502.

In FIGS. 2-5, sacrificial layers 214 are located under the semiconductor nanosheets 290 and extend from a first end 301 to a second end 302. Further, inner spacers 400 are located under the semiconductor nanosheets 290. Each inner spacer 400 abuts either a first end 301 or a second end 302 of a sacrificial layer 214.

As shown, each vertical stack of ends 201 (and each vertical stack of ends 202) is aligned and defines a vertical plane 299 perpendicular to the lateral Y-direction. As shown, the vertical plane 299 passes through each inner spacer 400 abutting the first end 301 of a sacrificial layer 214. At the opposite end, a vertical plane (not labeled) passes through each inner spacer 400 abutting the second end 302 of a sacrificial layer 214.

As shown in FIG. 3, each inner spacer 400 extends from an inner end 410 to an outer end 420. Thus, each inner spacer 400 terminates at the outer end 420. At the stage of fabrication of FIGS. 1-5, the inner end 410 abuts the first end 301 of the sacrificial layer 214. The outer end 420 abuts the source/drain region 500.

In some embodiments, the outer end 420 is formed with an outer portion 421 and a central recess 422.

Each inner spacer 400 is formed with a maximum width, i.e., a maximum lateral distance, D1, from the inner end 410 to a terminal location on the outer portion 421 of the outer end 420. In some embodiments, the maximum width is from 4.5 to 10 nanometers (nm). For example, the maximum width may be at least 4.5, at least 5, at least 5.5, at least 6, at least 6.5, at least 7, at least 7.5, at least 8, at least 8.5, at least 9, or at least 9.5 nanometers (nm). Further, the maximum width may be at most 10, at most 9.5, at most 9, at most 8.5, at most 8, at most 7.5, at most 7, at most 6.5, at most 6, at most 5.5, or at most 5.

Each inner spacer 400 is formed with a minimum width, i.e., a minimum lateral distance, D2, from the inner end 410 to the central recess 422 of the outer end 420. In some embodiments, the minimum width is from 4 to 7 nanometers (nm). For example, the maximum width may be at least 4, at least 4.5, at least 5, at least 5.5, at least 6, or at least 6.5 nanometers (nm). Further, the minimum width may be at most 7, at most 6.5, at most 6, at most 5.5, at most 5, or at most 4.5 nanometers (nm)

A respective vertical plane 299 passes through each inner spacer 400. As shown in FIG. 3, each inner spacer 400 extends from the inner end 410, past the vertical plane 299 to the outer end 420, and specifically to the outer portion 421 of the outer end 420. Thus, each inner spacer 400 extends past the vertical plane 299 by a lateral distance D3 from the vertical plane 299 to the outer portion 421. In some embodiments, distance D3 is from 0.5 to 3 nanometers (nm). For example, distance D3 may be at least 0.5, at least 1, at least 1.5, at least 2, or at least 2.5 nanometers (nm). Further, distance D3 may be at most 3, at most 2.5, at most 2, at most 1.5, or at most 1 nanometer (nm).

Accordingly, the inner end 410 may be distanced from the vertical plane 299 by a lateral distance D4. In some embodiments, distance D4 is from 4 to 7 nanometers (nm). For example, distance D4 may be at least 4, at least 4.5, at least 5, at least 5.5, at least 6, or at least 6.5 nanometers (nm). Further, distance D4 may be at most 7, at most 6.5, at most 6, at most 5.5, at most 5, or at most 4.5 nanometers (nm).

The central recess 422 may be aligned with a respective vertical plane 299 such that a lateral distance D5 defined between the central recess 422 and the vertical plane 299 may be zero. In some embodiments, the inner spacer may extend past the vertical plane 299 to the central recess 422, such that lateral distance D5 is greater than zero. For example, lateral distance D5 may be from 0 to 2 nanometers (nm). For example, the distance D5 may be at least 0.5, at least 1, or at least 1.5 nanometers (nm). Further, distance D5 may be at most 2, at most 1.5, at most 1, or at most 0.5 nanometers (nm). The distance D5 may be referred to as a minimum lateral distance between the vertical plane 299 and the outer end 420.

FIGS. 4-5 illustrate inner spacers 400 including a core 450 or air gap 450. The core 450 may be filled with a porous film comprising low-K dielectric material. As shown in FIG. 5, the core 450 is bounded or encapsulated by an interior wall 455 of the inner spacer 400. The core 450 has a lateral width W1 extending between opposite sides of the interior wall 455 and a vertical height H1 extending between opposite ends of the interior wall 455. In some embodiments, the lateral width W1 is from 1 to 4 nanometers (nm). For example, the lateral width W1 may be at least 1, at least 1.5, at least 2, at least 2.5, at least 3, or at least 3.5 nanometers (nm). Further, the lateral width W1 may be at most 4, at most 3.5, at most 3, at most 2.5, at most 2, or at most 1.5 nanometers (nm). In some embodiments, the vertical height H1 is from 1 to 3 nanometers (nm). For example, the vertical height H1 may be at least 1, at least 1.5, at least 2, or at least 2.5 nanometers (nm). Further, the vertical height H1 may be at most 3, at most 2.5, at most 2, or at most 1.5 nanometers (nm). In some embodiments, the volume or the core or gap 450 is from 20 to 60 percent of the total volume of the respective inner spacer 400.

Due to the dimensions of the inner spacers 400 and the cores or gaps 450 within the inner spacers 400, the AC gain of the device can be improved by 110 to 120%. Further, the effective capacitance (C_{eff}) of the device can be reduced by 2 to 10%.

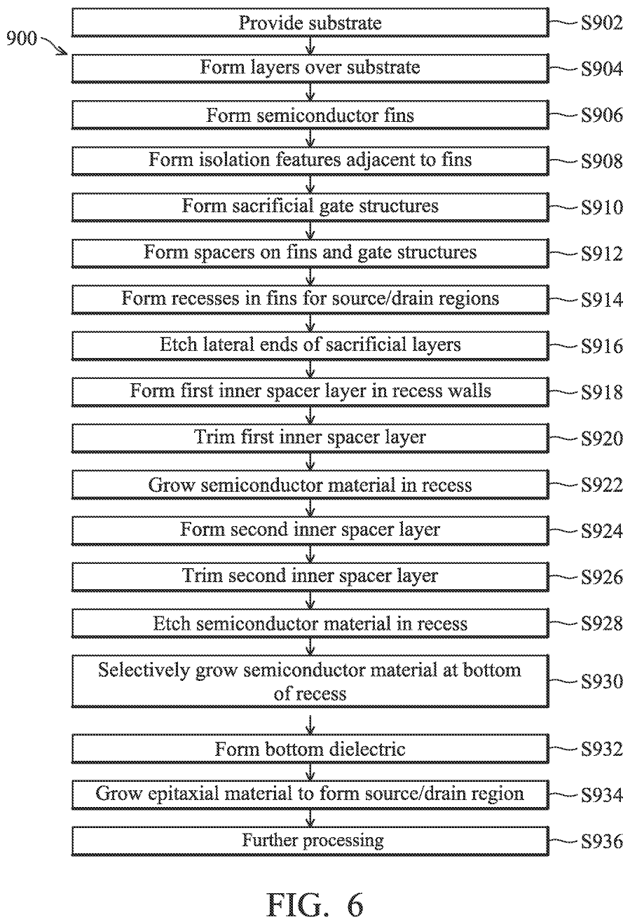

Referring now to FIG. 6, a method 900 for forming a structure, such as a multi-gate device 1000 according to embodiments in FIGS. 1-5, is illustrated in a flow chart, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as a “nanosheet”.

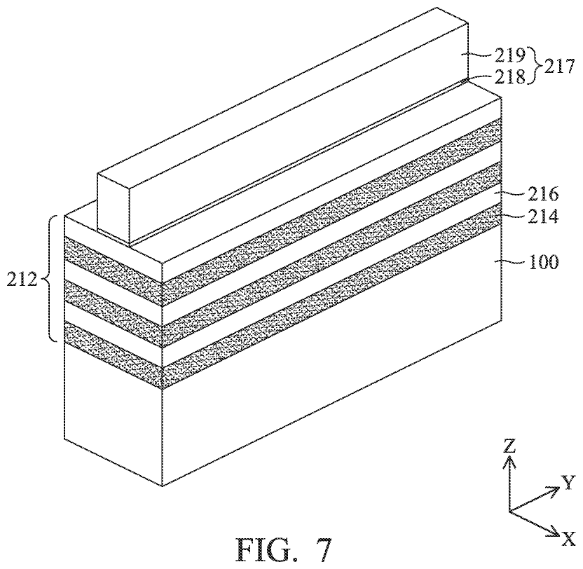

FIG. 6 is described in conjunction with FIGS. 7-24, which illustrate a semiconductor device 1000 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

As with the other method embodiments and exemplary devices discussed herein, it is understood that parts of the semiconductor device 1000 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 900, including any descriptions given with reference to the Figures, as with the remainder of the method and exemplary figures provided in this disclosure, are merely exemplary and are not intended to be limiting beyond what is specifically recited in the claims that follow.

At operation S902, the method 900 (FIG. 6) provides a substrate 100, as shown in FIG. 7. In some embodiments, the substrate 100 may be a semiconductor substrate such as a silicon (Si) substrate. The substrate 100 may include various layers, including conductive or insulating layers formed on a semiconductor substrate. The substrate 100 may include various doping configurations depending on design requirements as is known in the art. For example, different doping profiles (e.g., p-well, n-well) may be formed on the substrate 100 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 100 includes a single crystalline semiconductor layer on at least its surface portion. The substrate 100 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 100 may include a compound semiconductor and/or an alloy semiconductor. In the illustrated embodiment, the substrate 100 is made of crystalline Si.

As shown in FIG. 7, at operation S904, the method 900 (FIG. 6) forms one or more epitaxial layers over the substrate 100. In some embodiments, an epitaxial stack 212 is formed over the substrate 100. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. In an embodiment, the epitaxial layers 214 are SiGe and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 7, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 1000. In some embodiments, the number of epitaxial layers 216 is between two and ten, such as six or seven.

In some embodiments, the epitaxial layer 214 has a thickness ranging from 5 to 15 nm. The epitaxial layers 214 may be substantially uniform in thickness. In some embodiments, the epitaxial layer 216 has a thickness ranging from 5 to 15 nm. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 216 include the same material as the substrate 100. In some embodiments, the epitaxially grown layers 214 and 216 include a different material than the substrate 100. As stated above, in at least some examples, the epitaxial layer 214 includes an epitaxially grown Si₁₋ₓGeₓ layer (wherein x is from 0.10 to 0.55 and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from 0 cm⁻³ to 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

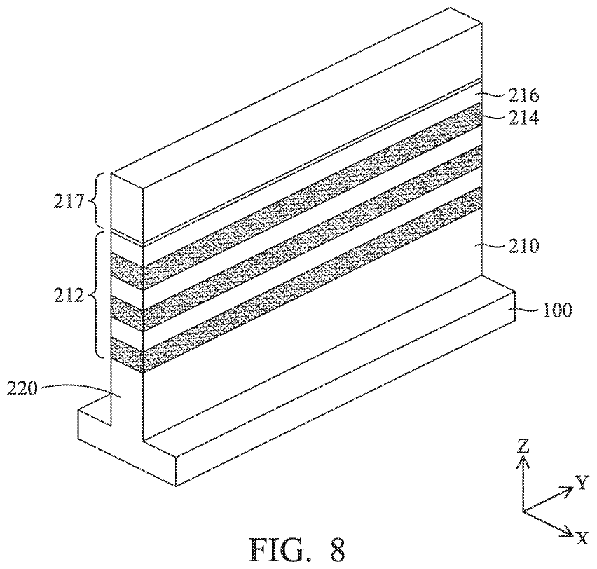

As shown in FIG. 8, at operation S906, the method 900 (FIG. 6) patterns the epitaxial stack 212 to form semiconductor fins 220. In some embodiments, the operation S906 includes forming a mask layer 217 over the epitaxial stack 212, as shown in FIG. 7. The mask layer 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer 217 is patterned into a mask pattern by using patterning operations including photolithography and etching.

As shown in FIG. 8, operation S906 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 216 are thereby patterned into the fin 220. While FIG. 8 illustrates the formation of one fin 220, any suitable number of the fins may be formed. Trenches are etched between adjacent fins 220.

In various embodiments, each fin 220 includes an upper portion of the interleaved epitaxial layers 214 and 216, and a bottom portion, or mesa portion 210, that is formed from the etched substrate 100. Each fin 220 protrudes upwardly in the Z-direction from the substrate 100 and extends lengthwise in the Y-direction. Sidewalls of each fin 220 may be straight or inclined (not shown). In FIG. 3, additional fins would be spaced apart along the X-direction. The fins 220 may have a same width or different widths.

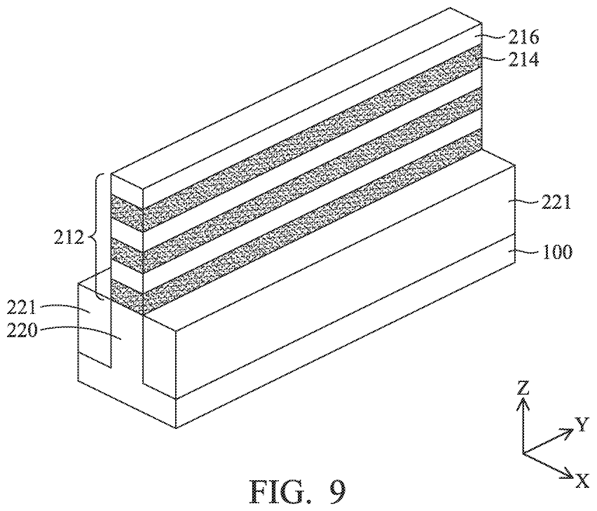

As shown in FIG. 9, at operation S908, the method 900 (FIG. 6) forms isolation features (also denoted as shallow trench isolation or STI features) 221 in trenches adjacent to each fin 220 with a dielectric layer. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 221, as shown in FIG. 4. In the illustrated embodiment, the STI features 221 are formed on the substrate 100. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask layer 217 (shown in FIG. 8) may also be removed before, during, and/or after the recessing of the isolation features 221. In some embodiments, the mask layer 217 is removed by the CMP process performed prior to the recessing of the isolation features 221. In some embodiments, the mask layer 217 is removed by an etchant used to recess the isolation features 221.

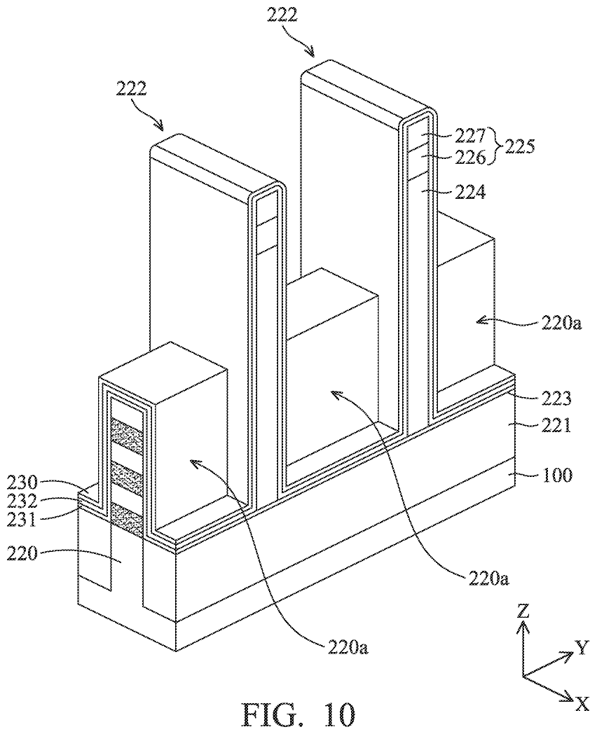

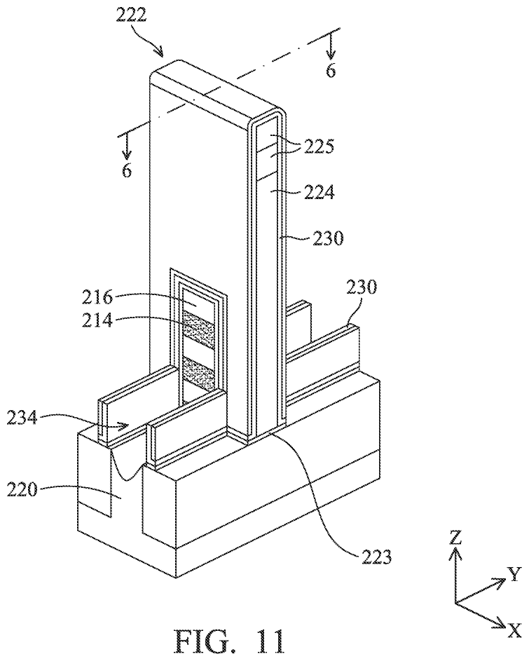

As shown in FIG. 10, at operation S910, the method 900 (FIG. 6) forms sacrificial (dummy) gate structures 222. The sacrificial gate structures 222 are formed over portions of the fin 220 which are to be channel regions. The sacrificial gate structures 222 may extend over a number of adjacent fins (not shown). The sacrificial gate structures 222 lie directly over and define the channel regions of the GAA devices to be formed. Each of the sacrificial gate structures 222 includes a sacrificial gate dielectric 223 and a sacrificial gate electrode 224 over the sacrificial gate dielectric 223. As shown, the gate structures 222 extend lengthwise in the X-direction and are spaced apart in the Y-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from 100 to 200 nm in some embodiments. The sacrificial gate electrode layer 224 includes silicon such as polycrystalline silicon or amorphous silicon. The thickness of the sacrificial gate dielectric layer is in a range from 1 to 5 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, a patterning operation is performed on the mask layer 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed between and on opposite sides of the sacrificial gate structures 222, thereby defining source/drain (S/D) regions. As used herein, “source/drain region(s)” may refer to a source region or a drain region, individually or collectively depending on the context.

Still referring to FIG. 10, at operation S912, the method 900 (FIG. 6) forms spacers 230 on sidewalls of the sacrificial gate structures 222 and sidewalls of the fins 220 by depositing spacer materials and then etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 on a sidewall of the liner layer 231.

By way of example, the spacers 230 may be formed by depositing spacer material including a liner material layer and a dielectric material layer over the sacrificial gate structures 222 using processes such as a subatmospheric CVD (SACVD) process, a flowable CVD process, an ALD process, a PVD process, or other suitable process respectively.

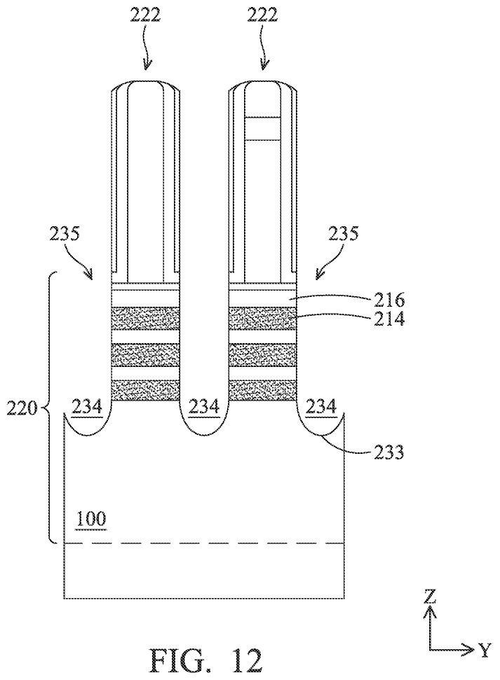

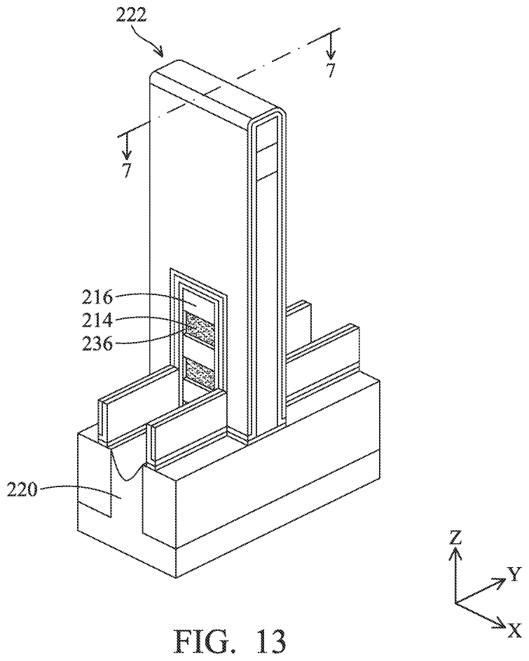

As shown in FIGS. 11 and 12, the deposition of the liner material layer and the dielectric material layer are followed by, at operation S914, an etching-back (e.g., anisotropic) process to expose, and remove, portions 220a of the fins 220 adjacent to and not covered by the sacrificial gate structure 222 (e.g., source/drain regions). Specifically, the method 900 (FIG. 6) recesses the portions of the fin 220 not covered by the sacrificial gate structures 222 to form cavities, gaps, or recesses 234 in the source/drain regions. It is noted that FIG. 11 shows only one sacrificial gate structure 222 and the adjacent portion of fin 220 so that etching of the S/D region between the sacrificial gate structures 222 of FIG. 10 may be more clearly viewed. FIG. 12 is a cross sectional-view along line 6-6 in FIG. 11 but, like FIG. 10, FIG. 12 illustrates both sacrificial gate structures 222 and the fin 220 adjacent to both sacrificial gate structures 222.

The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from 5 to 20 nm.

As shown most clearly in FIG. 12, the stacked epitaxial layers 214 and 216 and an upper portion of substrate 100 forming fin 220 are etched down at the S/D regions. As a result, a bottom gap surface 233 is formed in the fin 220. In some embodiments, the operation S914 forms the gaps 234 by a suitable etching process, such as a dry etching process, a wet etching process, or a combination thereof. As a result of the etching process, fin segments 235 of the upper portion of the fin 220 are defined and separated from one another by the gaps 234.

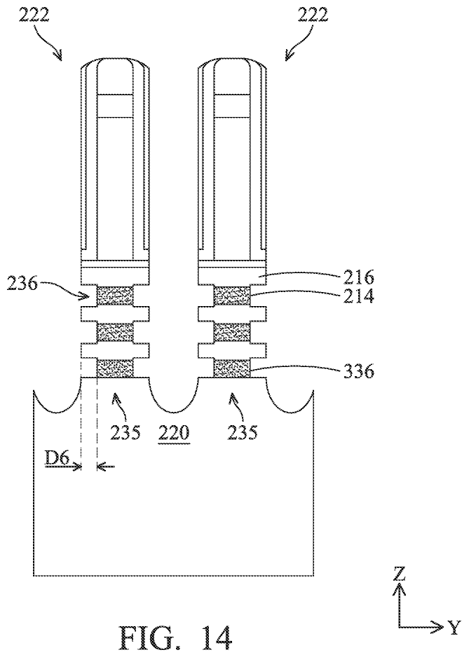

As shown in FIGS. 13 and 14, at operation S916, the method 900 (FIG. 6) etches the lateral ends of the epitaxial layers 214 in the Y-direction to recessed surfaces 336, thereby forming cavities 236. For example, operation S916 may etch the epitaxial layers 214 by a lateral distance D6. In exemplary embodiments, lateral distance D6 is less than maximum lateral distance, D1. In some embodiments, the lateral distance D6 is from 4 to 9.5 nanometers (nm). For example, the lateral distance D6 may be at least 4, at least 4.5, at least 5, at least 5.5, at least 6, at least 6.5, at least 7, at least 7.5, at least 8, at least 8.5, or at least 9 nanometers (nm). Further, the maximum width may be at most 9.5, at most 9, at most 8.5, at most 8, at most 7.5, at most 7, at most 6.5, at most 6, at most 5.5, at most 5, or at most 4.5 nanometers (nm).

It is noted that FIG. 13, similar to FIG. 11, shows only one sacrificial gate structure 222 and the adjacent portion of fin 220 and so that etching of the source/drain region between the sacrificial gate structures 222 may be viewed.

FIG. 14 is a cross-sectional view along line 7-7 of the structure in FIG. 13 but, like FIGS. 10 and 12, illustrates both sacrificial gate structures 222 and the adjacent fin 220.

The amount of etching of the epitaxial layers 214 is in a range from 3 to 8 nm, such as from 4 to 7 nm, in some embodiments. The epitaxial layers 214 may be selectively etched by using a wet etchant such as, but not limited to, ammonium hydroxide (NH4OH), tetramethylammonium hydroxide (TMAH), ethylenediamine pyrocatechol (EDP), potassium hydroxide (KOH), HF, O3, H2O2, or HCl solutions. Alternatively, the operation S916 may first selectively oxidize lateral ends of the epitaxial layers 214 that are exposed in the gaps 234 to increase the etch selectivity between the epitaxial layers 214 and 216. In some examples, the oxidation process may be performed by exposing the GAA device 1000 to a wet oxidation process, a dry oxidation process, or a combination thereof.

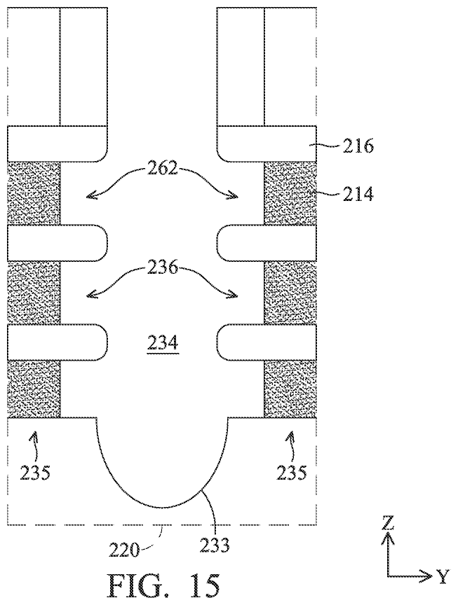

FIGS. 15 to 23 focus on the gap 234 located between fin segments 235 for further description of the method 900. As shown in FIG. 15, opposite gap sidewalls 262 are formed by the alternating semiconductor layers 214 and 216. Further, a bottom gap surface 233 is formed in the fin structure 220.

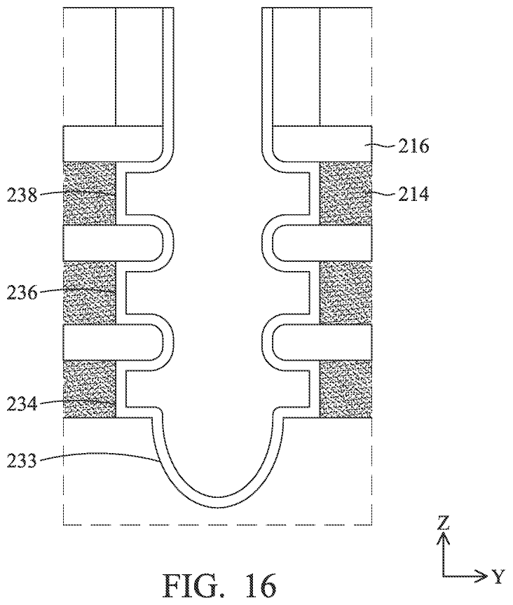

As shown in FIG. 16, method 900 (FIG. 6) may continue with operation S918 which forms a first inner spacer material layer 238 in the gap 234. Specifically, the first inner spacer material is deposited in the gap 234 on the gap sidewalls 262, including on the lateral ends of the epitaxial layer 214, and on the ends and top and bottom surfaces of the epitaxial layers 216, and on the bottom gap surface 233. The first inner spacer material layer 238 may include silicon oxides, silicon nitrides, silicon carbides, silicon carbide nitride, silicon oxide carbide, silicon carbide oxynitride, and/or other suitable dielectric materials. In some embodiments, the inner spacer material layer 238 is deposited as a conformal layer. The first inner spacer material layer 238 may be formed by ALD or any other suitable method. The first inner spacer material layer 238 may have a thickness ranging from 1 to 5 nm, for example from 1 to 4 nm, from 1 to 3 nm, or from 1 to 2 nm.

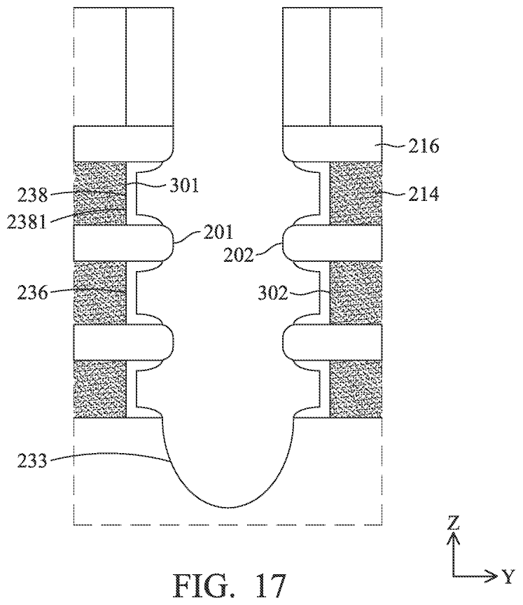

As shown in FIG. 17, method 900 (FIG. 6) may continue with operation S920 which trims the first inner spacer material layer 238. In some embodiments, the first inner spacer material layer 238 is removed from the lateral ends 201 and 202 of the epitaxial layers 216 and from the bottom gap surface 233, while a remaining portion 2381 of the first inner spacer material layer 238 remains on the lateral ends 301 and 302 of the sacrificial layers 214, and on top and bottom surfaces of the epitaxial layers 216.

Removal of the portions of the first inner spacer material layer 238 may be performed by an etching process, such as an anisotropic etching process, for example a dry etching process. In some embodiments, the dry etching process using an etchant including a fluorine-containing gas (e.g., SF₆, CF₄, CHF₃, CH₂F₂, and/or C₂F₆), a chlorine-containing gas (e.g., Cl₂), a bromine-containing gas (e.g., HBr and/or CHBR₃), oxygen-containing gas (e.g., O₂), a helium-containing gas (e.g., He), an argon-containing gas (e.g., Ar), other suitable gases, or combinations thereof. By this etching, the first inner spacer material layer 238 remains substantially within the cavities 236, because of small volumes of the cavities 236. Generally, plasma dry etching etches a layer in wide and flat areas faster than a layer in concave (e.g., holes, grooves, recesses and/or slits) portions. Thus, the first inner spacer material layer 238 may remain inside the cavities 236.

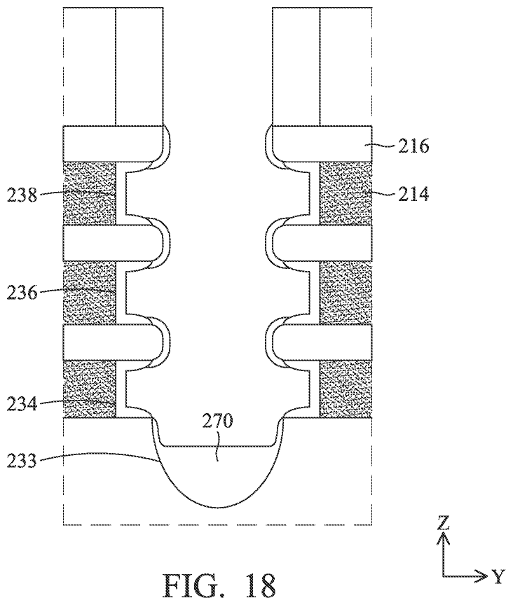

As shown in FIG. 18, method 900 (FIG. 6) may continue with operation S922 which selectively grows semiconductor material 270 on the ends 201 and 202 of epitaxial layers 216 and on the gap bottom surface 233. For example, undoped silicon may be grown as epitaxial semiconductor material 270 on the semiconductor material forming the epitaxial layers 216 and gap bottom surface 233.

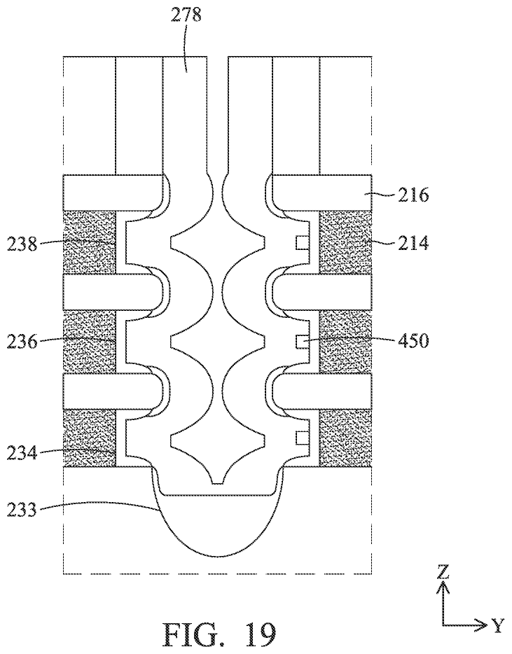

As shown in FIG. 19, method 900 (FIG. 6) may continue with operation S924 which forms a second inner spacer material layer 278 in the gap 234. Specifically, the second inner spacer material layer 278 is deposited on the first inner spacer material layer 238 and on the semiconductor material 270. The second inner spacer material layer 278 may include silicon oxides, silicon nitrides, silicon carbides, silicon carbide nitride, silicon oxide carbide, silicon carbide oxynitride, and/or other suitable dielectric materials. The second inner spacer material layer 278 may have a thickness greater than the first inner spacer material layer 238. For example, the second inner spacer material layer 278 may have a thickness of from 4 to 12 nm, for example at least 5, at least 6, at least 7, or at least 8 nm, and at most 11, at most 10, at most 8, or at most 8 nm.

As shown, operation S924 may include forming cores or air gaps 450. Specifically, due to the overhang profile of the semiconductor material 270 formed on the ends of the epitaxial layers 216, cores or air gaps 450 may be formed at the interface of the first inner spacer material layer 238 and the second inner spacer material layer 278 (as shown on the right side of FIG. 19), or within the second inner spacer material layer 278.

Thus, in some embodiments, cores 450, filled with air, are enclosed by the second inner spacer material layer 278 or by the first inner spacer material layer 238 and the second inner spacer material layer 278. In other embodiments, a low-K dielectric material (such as SiN, SiCN, SIOCN, SiOC, SiON) may be deposited to form the cores 450. In some embodiments, the core 450 is encapsulated, at least partially by the second inner spacer material layer 278. In some embodiments, the core 450 is porous.

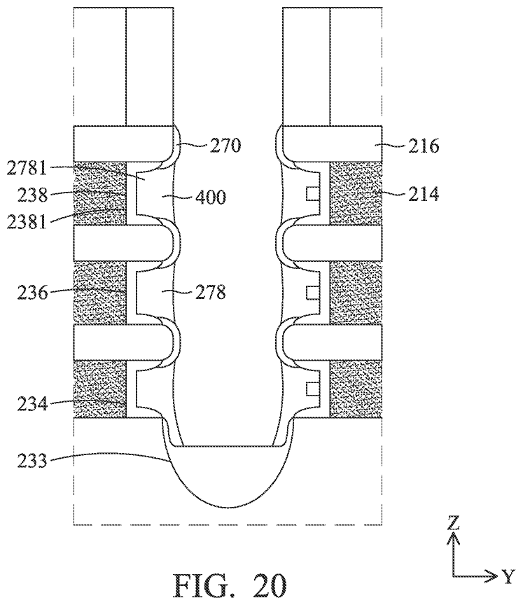

As shown in FIG. 20, method 900 (FIG. 6) may continue with operation S926 which trims the second inner spacer material layer 278. In some embodiments, the second inner spacer material layer 278 is removed from portions of the semiconductor material 270 on the lateral ends 201 and 202 of the epitaxial layers 216 and from most of the bottom gap surface 233, while a remaining portion 2781 of the second inner spacer material layer 278 remains covering the first inner spacer material layer 238.

Removal of the portions of the second inner spacer material layer 278 may be performed by an etching process, such as an anisotropic etching process, for example a dry etching process. In some embodiments, the dry etching process using an etchant including a fluorine-containing gas (e.g., SF₆, CF₄, CHF₃, CH₂F₂, and/or C₂F₆), a chlorine-containing gas (e.g., Cl₂), a bromine-containing gas (e.g., HBr and/or CHBR₃), oxygen-containing gas (e.g., O₂), a helium-containing gas (e.g., He), an argon-containing gas (e.g., Ar), other suitable gases, or combinations thereof. By this etching, the second inner spacer material layer 278 substantially fills the cavities 236. Generally, plasma dry etching etches a layer in wide and flat areas faster than a layer in concave (e.g., holes, grooves, recesses and/or slits) portions. Thus, the first inner spacer material layer 238 remains inside the cavities 236.

As a result of trimming the second inner spacer material layer 278, inner spacers 400 are defined. Each inner spacer 400 is formed by a remaining portion 2381 of the first inner spacer material layer 238, a remaining portion 2781 of the second inner spacer material layer 278, and a core 450, if present.

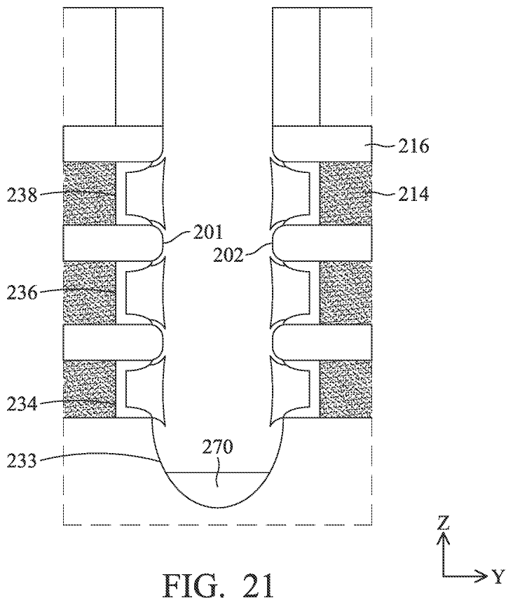

As shown in FIG. 21, method 900 (FIG. 6) may continue with operation S928 which etches the semiconductor material 270 grown at operation S922. Specifically, a process for selectively etching undoped silicon may be performed to remove the semiconductor material 270. As a result, the semiconductor material 270 on the ends 201 and 202 of the epitaxial layers 216 may be completely removed and the ends 201 and 202 of the epitaxial layers 216 may be uncovered. Further, the semiconductor material 270 on the gap bottom surface 233 may be recessed, as shown.

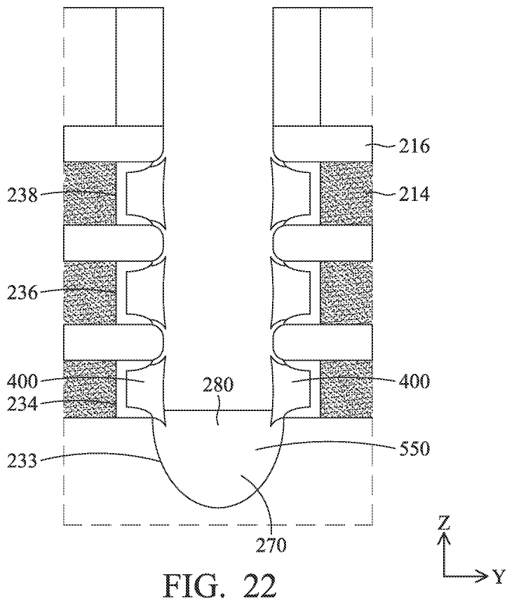

As shown in FIG. 22, method 900 (FIG. 6) may continue with operation S930 which selectively grows semiconductor material 280 over the semiconductor material 270 and the gap bottom surface 233. As shown, the semiconductor material 280 is not grown on the ends 201 and 202 of the epitaxial layers 216. The semiconductor material 280 may contact and extend between the lowest opposite inner spacers 400. Collectively, the semiconductor materials 270 and 280 may form a bottom epitaxial region 550.

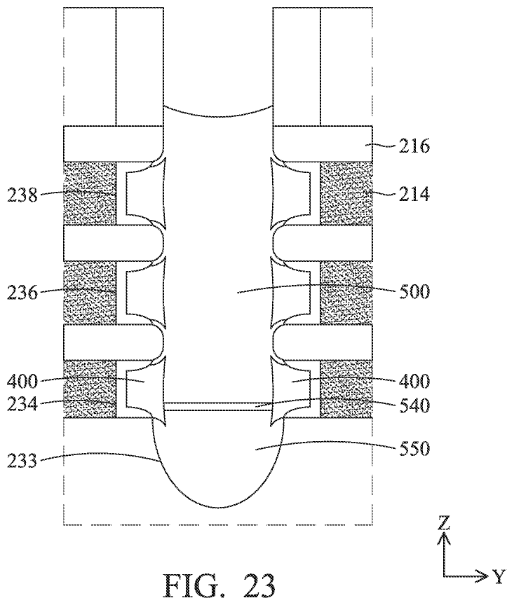

As shown in FIG. 23, method 900 (FIG. 6) may continue with operation S932 which forms a bottom dielectric layer 560 over the bottom epitaxial region 550. For example, a dielectric material may be deposited and trimmed to form the bottom dielectric layer 560. As shown, the bottom dielectric layer 560 contacts and extends between the lowest opposite inner spacers 400.

Further, as shown in FIG. 23, method 900 (FIG. 6) may continue with operation S934 which grows epitaxial material in the recess to form a source/drain structure 500. It is noted that the source/drain structure 500 may be formed by successive formed layers. Also, the source/drain structure 500 may be formed with layers selected for use in an NFET or PFET. The epitaxial source/drain structure 500 may be formed by an epitaxial growth method using CVD, ALD or molecular beam epitaxy (MBE). The epitaxial structures 500 may include SiGe for PFETs, and silicon for NFETs.

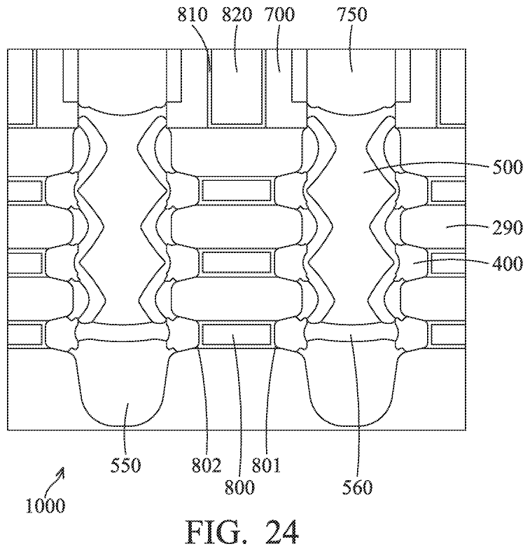

In FIG. 24, method 900 (FIG. 6) may continue with further processing at operation S936. For example, interlayer dielectric 750 may be formed over the source/drain structures 500 and between spacer structures 700. Further, the sacrificial gates 222, including the sacrificial gate electrode and the sacrificial gate dielectric, and the sacrificial layers 214 are removed and replaced in a replacement metal gate process. For example, metal gates 800 may be formed, including a gate dielectric layer 810 and a metal electrode 820. After removal of the sacrificial layers 214 and formation of the metal gates 800, the remaining epitaxial layers 216 may be referred to as semiconductor nanosheets 290. As shown, the gate dielectric 810 may be formed around the nanosheets 290, and the metal gate electrode material 820 may be deposited over the gate dielectric 810 to form the metal gate 800. As shown, the metal gate 800 abuts the ends 410 of the inner spacers 400. Specifically, the metal gate 800 extends from an end 801 to an end 802. End 801 abuts an inner spacer 400 and end 802 abuts an inner spacer 400.

In certain embodiments, the replacement metal gate process may include a wire-release process to form vertically-spaced nanosheets, in accordance with some embodiments. The wire release process step may also be referred to as a sheet release process step, a sheet formation process step, a nanosheet formation process step or a wire formation process step. In an embodiment the first layers 214 may be removed using a wet etching process that selectively removes the material of the first layers (e.g., silicon germanium (SiGe)) without significantly removing the material of the second layers 216 (e.g., silicon (Si)). However, any suitable removal process may be utilized.

For example, in an embodiment, an etchant such as a high temperature HCl may be used to selectively remove the material of the first layers 214 (e.g., SiGe) without substantively removing the material of the second layers 216 (e.g., Si). Additionally, the wet etching process may be performed at a temperature of from 400° C. to 600° C., such as about 560° C., and for a time of from 100 seconds to 600 seconds, such as about 300 seconds. However, any suitable etchant, process parameters, and time can be utilized.

According to some embodiments, the gate dielectric 810 comprises a high-K material (e.g., a material with a K value greater than or equal to 9) such as Ta₂O₅, Al₂O₃, Hf oxides, Ta oxides, Ti oxides, Zr oxides, Al oxides, La oxides (e.g., HfO₂, HfSiO, HfSION, HfTaO, HfTiO, HfZrO, LaO, ZrO, TiO), combinations of these, or the like, deposited through a process such as atomic layer deposition, chemical vapor deposition, or the like. In some embodiments, the gate dielectric 810 comprises a nitrogen doped oxide dielectric that is initially formed prior to forming a metal content high-K (e.g., K value>13) dielectric material. The gate dielectric 810 may be deposited to a thickness of from 1 to 3 nm, although any suitable material and thickness may be utilized.

According to some embodiments, the metal electrode 820 is formed using multiple layers, each layer deposited sequentially adjacent to each other using a highly conformal deposition process such as atomic layer deposition, although any suitable deposition process may be utilized. According to some embodiments, a capping layer, a barrier layer, an n-metal work function layer, a p-metal work function layer, and a fill material may be provided.

The capping layer may be formed adjacent to the gate dielectric 810 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC. TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W, Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

After the openings left behind by the removal of the dummy gates 222 have been filled, the materials of the metal electrode 820 and the gate dielectric 810 may be planarized in order to remove any material that is outside of the openings left behind by the removal of the dummy gates 222. In a particular embodiment the removal may be performed using a planarization process such as chemical mechanical polishing, although any suitable planarization and removal process may be utilized. According to some embodiments, the metal gates 800 may be formed to a vertical height, in the Z-direction, of from 70 nm to 85 nm. However, any suitable height may be used.

Further processing may include the formation and patterning of additional dielectric and conductive layers and typically Back-End-Of-Line (BEOL) processing.

As described herein, embodiments provide for inner spacers with an increased lateral width, and which extend past the inner ends of nanosheets and into source/drain regions. Further, such inner spacers may be formed with internal low-K cores or air gaps.

In an embodiment, a method includes etching a cavity in a vertical direction into a fin structure including at least one semiconductor nanosheet overlying a sacrificial layer, wherein the cavity is formed with a sidewall; recessing the sacrificial layer by a lateral distance to a recessed surface; forming an inner spacer laterally adjacent to the recessed surface of the sacrificial layer, wherein the inner spacer has a lateral width greater than the lateral distance; and growing epitaxial material in the cavity to form a source/drain region laterally adjacent to the inner spacer.

In an embodiment of the method, the lateral distance is from 4 to 7 nanometers (nm) and wherein the lateral width is from 5 to 10 nanometers (nm).

In an embodiment of the method, the inner spacer is formed with an internal core filled with air or a low-K material.

In an embodiment of the method, the internal core has a lateral width of from 1 to 4 nanometers; and the internal core has a vertical height of from 1 to 3 nanometers.

In an embodiment of the method, the recessed surface is distanced from an end of the semiconductor nanosheet by the lateral distance; the end of the semiconductor nanosheet defines a vertical plane; and the vertical plane passes through the inner spacer.

In an embodiment of the method, the end of the semiconductor nanosheet defines a vertical plane; the inner spacer extends laterally from the recessed surface to an outer end; the outer end is distanced from the vertical plane by a maximum lateral distance; and the maximum lateral distance is from 0.5 to 3 nanometers (nm).

In an embodiment of the method, the outer end of the inner spacer is formed with an outer portion and a central recess; the maximum lateral distance is defined at a location on the outer portion; a minimum lateral distance is defined between the vertical plane and the central recess; and the minimum lateral distance is from 0 to 2 nanometers (nm).

In another embodiment, a method includes etching a cavity in a vertical direction into a fin structure including at least one semiconductor nanosheet overlying a sacrificial layer; performing a lateral recess process to etch the sacrificial layer in a lateral direction perpendicular to the vertical direction, wherein the sacrificial layer is formed with a recessed surface; depositing a first inner spacer layer in the cavity, wherein the first inner spacer layer is located adjacent to the semiconductor nanosheet and on the recessed surface of the sacrificial layer; removing the first inner spacer layer from the semiconductor nanosheet, wherein a remaining portion of the first inner spacer layer remains on the recessed surface of the sacrificial layer; growing semiconductor material on the semiconductor nanosheet; depositing a second inner spacer layer in the cavity, wherein the second inner spacer layer is located adjacent to the semiconductor material and to the remaining portion of the first inner spacer layer; and removing the second inner spacer layer from the semiconductor material, wherein a remaining portion of the second inner spacer layer remains on the remaining portion of the first inner spacer layer.

In an embodiment, the method further includes removing the semiconductor material from the semiconductor nanosheet.

In an embodiment, the method further includes selectively growing additional semiconductor material at a bottom of the cavity.

In an embodiment, the method further includes forming a dielectric layer over the additional semiconductor material at the bottom of the cavity; and growing epitaxial material in the cavity over the dielectric layer to form a source/drain region.

In an embodiment of the method, the remaining portion of the first inner spacer layer and the remaining portion of the second inner spacer layer form an inner spacer; the semiconductor nanosheet terminates at an end abutting the source/drain region; the end defines a vertical plane; and the vertical plane passes through the inner spacer.

In an embodiment of the method, the remaining portion of the first inner spacer layer and the remaining portion of the second inner spacer layer form an inner spacer; the semiconductor nanosheet terminates at an end abutting the cavity; and the inner spacer extends laterally past the end of the semiconductor nanosheet and into the cavity.

In an embodiment of the method, depositing the second inner spacer layer in the cavity includes trapping an air pocket within the second inner spacer layer.

In an embodiment of the method, the air pocket has a lateral width of from 1 to 4 nanometers; and the air pocket has a vertical height of from 1 to 3 nanometers.

In another embodiment, a semiconductor device includes a first source/drain region distanced from a second source/drain region in a lateral Y-direction; a fin structure including a semiconductor nanosheet, wherein the semiconductor nanosheet extends in the lateral Y-direction from a first end adjacent the first source/drain region to a second end adjacent the second source/drain region, wherein the first end defines a first vertical plane perpendicular to the lateral Y-direction; a portion of a gate structure located under the semiconductor nanosheet and extending from a first end to a second end; and an inner spacer located under the semiconductor nanosheet and abutting the first end of the portion of the gate structure, wherein the first vertical plane passes through the inner spacer.

In an embodiment of the device, the inner spacer includes a dielectric material surrounding a core formed by air or by a low-K dielectric material.

In an embodiment of the device, the core has a lateral width of from 1 to 4 nanometers; and the core has a vertical height of from 1 to 3 nanometers.

In an embodiment of the device, the inner spacer extends from an inner end to an outer end; the inner end abuts the first end of the portion of the gate structure; the outer end is located at a maximum lateral distance from the vertical plane; and the maximum lateral distance is from 0.5 to 3 nanometers (nm).

In an embodiment of the device, the outer end of the inner spacer is formed with an outer portion and a central recess; the maximum lateral distance is defined at a location on the outer portion; a minimum lateral distance is defined between the vertical plane and the central recess; and the minimum lateral distance is from 0 to 2 nanometers (nm).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
etching a cavity in a vertical direction into a fin structure including at least one semiconductor nanosheet overlying a sacrificial layer, wherein the cavity is formed with a sidewall;
recessing the sacrificial layer by a lateral distance to a recessed surface;
forming an inner spacer laterally adjacent to the recessed surface of the sacrificial layer, wherein the inner spacer has a lateral width greater than the lateral distance; and
growing epitaxial material in the cavity to form a source/drain region laterally adjacent to the inner spacer.

2. The method of claim 1, wherein the lateral distance is from 4 to 7 nanometers (nm) and wherein the lateral width is from 5 to 10 nanometers (nm).

3. The method of claim 1, wherein the inner spacer is formed with an internal core filled with air or a low-K material.

4. The method of claim 3, wherein:
the internal core has a lateral width of from 1 to 4 nanometers; and
the internal core has a vertical height of from 1 to 3 nanometers.

5. The method of claim 1, wherein:
the recessed surface is distanced from an end of the semiconductor nanosheet by the lateral distance;
the end of the semiconductor nanosheet defines a vertical plane; and
the vertical plane passes through the inner spacer.

6. The method of claim 1, wherein:
the end of the semiconductor nanosheet defines a vertical plane;
the inner spacer extends laterally from the recessed surface to an outer end;
the outer end is distanced from the vertical plane by a maximum lateral distance; and
the maximum lateral distance is from 0.5 to 3 nanometers (nm).

7. The method of claim 6, wherein:
the outer end of the inner spacer is formed with an outer portion and a central recess;
the maximum lateral distance is defined at a location on the outer portion;
a minimum lateral distance is defined between the vertical plane and the central recess; and
the minimum lateral distance is from 0 to 2 nanometers (nm).

8. A method comprising:
etching a cavity in a vertical direction into a fin structure including a semiconductor nanosheet overlying a sacrificial layer;
performing a lateral recess process to etch the sacrificial layer in a lateral direction perpendicular to the vertical direction, wherein the sacrificial layer is formed with a recessed surface;
depositing a first inner spacer layer in the cavity, wherein the first inner spacer layer is located adjacent to the semiconductor nanosheet and on the recessed surface of the sacrificial layer;
removing the first inner spacer layer from the semiconductor nanosheet, wherein a remaining portion of the first inner spacer layer remains on the recessed surface of the sacrificial layer;
growing semiconductor material on the semiconductor nanosheet;
depositing a second inner spacer layer in the cavity, wherein the second inner spacer layer is located adjacent to the semiconductor material and to the remaining portion of the first inner spacer layer; and
removing the second inner spacer layer from the semiconductor material, wherein a remaining portion of the second inner spacer layer remains on the remaining portion of the first inner spacer layer.

9. The method of claim 8, further comprising removing the semiconductor material from the semiconductor nanosheet.

10. The method of claim 9, further comprising selectively growing additional semiconductor material at a bottom of the cavity.

11. The method of claim 10, further comprising:
forming a dielectric layer over the additional semiconductor material at the bottom of the cavity; and
growing epitaxial material in the cavity over the dielectric layer to form a source/drain region.

12. The method of claim 11, wherein:
the remaining portion of the first inner spacer layer and the remaining portion of the second inner spacer layer form an inner spacer;
the semiconductor nanosheet terminates at an end abutting the source/drain region;
the end defines a vertical plane; and
the vertical plane passes through the inner spacer.

13. The method of claim 8, wherein:
the remaining portion of the first inner spacer layer and the remaining portion of the second inner spacer layer form an inner spacer;
the semiconductor nanosheet terminates at an end abutting the cavity; and
the inner spacer extends laterally past the end of the semiconductor nanosheet and into the cavity.

14. The method of claim 8, wherein depositing the second inner spacer layer in the cavity comprises trapping an air pocket within the second inner spacer layer.

15. The method of claim 14, wherein:
the air pocket has a lateral width of from 1 to 4 nanometers; and
the air pocket has a vertical height of from 1 to 3 nanometers.

16. A semiconductor device comprising:
a first source/drain region distanced from a second source/drain region in a lateral Y-direction;
a fin structure including a semiconductor nanosheet, wherein the semiconductor nanosheet extends in the lateral Y-direction from a first end adjacent the first source/drain region to a second end adjacent the second source/drain region, wherein the first end defines a first vertical plane perpendicular to the lateral Y-direction;
a portion of a gate structure located under the semiconductor nanosheet and extending from a first end to a second end; and
an inner spacer located under the semiconductor nanosheet and abutting the first end of the portion of the gate structure, wherein the first vertical plane passes through the inner spacer.

17. The semiconductor device of claim 16, wherein the inner spacer comprises a dielectric material surrounding a core formed by air or by a low-K dielectric material.

18. The semiconductor device of claim 17, wherein:
the core has a lateral width of from 1 to 4 nanometers; and
the core has a vertical height of from 1 to 3 nanometers.

19. The semiconductor device of claim 16, wherein:
the inner spacer extends from an inner end to an outer end;
the inner end abuts the first end of the portion of the gate structure;
the outer end is located at a maximum lateral distance from the first vertical plane; and
the maximum lateral distance is from 0.5 to 3 nanometers (nm).

20. The semiconductor device of claim 19, wherein:
the outer end of the inner spacer is formed with an outer portion and a central recess;
the maximum lateral distance is defined at a location on the outer portion;
a minimum lateral distance is defined between the first vertical plane and the central recess; and
the minimum lateral distance is from 0 to 2 nanometers (nm).
